(19) United States
(12) Patent Application Publication
(10) Pub. No.: US 2003/0151139 A1
(43) Pub. Date: Aug. 14, 2003

(54) Semiconductor device

(75) Inventor: Naoto Kimura, Kumamoto-Shi (JP)

Correspondence Address: YOUNG & THOMPSON, 745 SOUTH 23RD STREET 2ND FLOOR, ARLINGTON, VA, 22202

(73) Assignee: NEC ELECTRONICS CORPORATION, KANAGAWA (JP)

(21) Appl. No.: 10/352,036

(22) Filed: Jan. 28, 2003

(30) Foreign Application Priority Data
Feb. 13, 2002 (JP) 2002-035400

(51) Int. Cl. H01L 23/48; H01L 23/52; H01L 29/40

(52) U.S. Cl. 257/737

(57) ABSTRACT

In a semiconductor device including a metal substrate having one surface on which a semiconductor chip is mounted and the other surface on which solder balls are mounted, the semiconductor chip is electrically connected to the solder balls through through-holes formed in the substrate and bonding wires. An insulating film is formed on a whole surface of the substrate including inner surface of the through-holes and the solder balls are supported by the through-holes, so that a wiring connected to the electrically conductive through-holes and the semiconductor chip are electrically connected by the bonding wires. Diameter of the through-hole in the other surface of the substrate on which the solder ball is supported is larger than diameter of the through-hole in the one surface of the substrate.

### BACKGROUND OF THE INVENTION

1. Field of the Invention

The present invention relates to a semiconductor device and, in particular, the present invention relates to a semiconductor device having large calorimetric power.

2. Description of the Prior Art

It has been usual that a semiconductor device having large calorimetric power includes a substrate and a heat spreader or a heat sink. A first example of a conventional semiconductor device having large calorimetric power is disclosed in JPH10-199899A.

The conventional semiconductor device according to the first example includes a substrate formed of a plastic material and a heat radiating plate called heat spreader.

A second and third examples of the conventional semiconductor device having substrates formed of plastic materials are disclosed in JPH11-97586A and JP2001-274202A, respectively.

A fourth example of the conventional semiconductor device shown in FIG. 4 of JPH8-55931A has a substrate formed with large through-holes. In the fourth example, a wiring is formed by forming a metal foil on the substrate and etching the metal foil.

In the first example disclosed in JPH10-199899A, since a size of a semiconductor chip portion mounted on the substrate is not enough to mount solder halls, a semiconductor device package size becomes large. Further, heat radiation of each of the second and third examples is not acceptable because the plastic substrate is used.

When, in the fourth example, the wiring is formed on the substrate by vapor-deposition in vertically downward, it is difficult to form a fine wiring since the vapor deposited metal foil portions on the large through-holes are caved. Further, since, in the fourth example, the wiring is formed by laminating a plurality of metal foils each suitably patterned by etching on the substrate, it is difficult to obtain a wiring width not larger than 25 μm.

Further, in the fourth example, it is difficult to form small through-holes since the through-holes are formed by etching the substrate from only a lower surface thereof. This is because the size of through-holes varies due to variation of reaction speed of etching. Therefore, it is necessary to increase the size of upper connecting portions of the wiring and so the number of wiring lines formed between the connecting portions is reduced.

### SUMMARY OF THE INVENTION

Therefore, an object of the present invention is to provide a low cost substrate of a semiconductor device having calorimetric power large enough to require a heat spreader and to reduce a package size of the semiconductor device by mounting solder balls on the low cost substrate.

In a semiconductor device including a heat radiating substrate, a semiconductor chip mounted on one surface of the heat radiating substrate and solder balls mounted on the other surface of the heat radiating substrate, the present invention achieves the above object by electrically connecting the semiconductor chip to the solder bails by means of a plurality of through-holes formed in the substrate and bonding wires. According to an embodiment of the present invention, an insulating film is formed on a whole surface of the substrate including inner surfaces of the through-holes, which support the respective solder balls, and a wiring formed on the one surface of the substrate and connected to the electrically conductive through-holes having the inner surface, which are made electrically conductive by the solder balls, and the semiconductor chip are electrically connected each other by the bonding wires. A diameter of the through-hole on the other side surface of the substrate by which the solder ball is supported is made larger than a diameter of the through-hole on the one surface side of the substrate.

According to another embodiment of the present invention, a wiring is formed on the other surface of the substrate and the semiconductor chip mounted on the one surface of the substrate is electrically connected directly to the wiring by the bonding wires passing through the through-holes.

According to the present invention, since the wiring can be formed by vapor deposition, it is possible to realize a wiring width not larger than 0.5 μm.

In a preferred embodiment of the present invention, a semiconductor device package in which electrodes on a semiconductor chip are connected to a wiring of the package by thin metal lines comprises a substrate on which the semiconductor chip and solder balls are mounted, the substrate having first holes formed on one surface of the substrate for mounting the solder balls, second holes each having diameter smaller than diameter of the first hole and formed in the other surface of the substrate, an insulating film formed on a whole surface of the substrate and a wiring of an electrically conductive metal formed on the insulating film, wherein the first holes are in communication with the second holes, respectively.

The substrate of the semiconductor device of the present invention is preferably formed of a metal material selected from a group consisting of copper, titanium, aluminum and iron, etc.

### BRIEF DESCRIPTION OF THE DRAWINGS

FIG. 1 is a cross sectional view of a semiconductor device according to a first embodiment of the present invention;

FIG. 2 is a first cross sectional view of the semiconductor device shown in FIG. 1, illustrating a first step of a fabrication flow thereof;

FIG. 3 is a second cross sectional view of the semiconductor device shown in FIG. 1, illustrating a second step of the fabrication flow thereof;

FIG. 4 is a third cross sectional view of the semiconductor device shown in FIG. 1, illustrating a third step of the fabrication flow thereof;

FIG. 5 is a fourth cross sectional view of the semiconductor device shown in FIG. 1, illustrating a fourth step of the fabrication flow thereof;

FIG. 6 is a fifth cross sectional view of the semiconductor device shown in FIG. 1, illustrating a fifth step of the fabrication flow thereof;

FIG. 7 is a sixth cross sectional view of the semiconductor device shown in FIG. 1, illustrating a sixth step of the fabrication flow thereof;

FIG. 8 is a seventh cross sectional view of the semiconductor device shown in FIG. 1, illustrating a seventh step of the fabrication flow thereof; and

FIG. 9 is a cross sectional view of a semiconductor device according to a second embodiment of the present invention.

### DETAILED DESCRIPTION OF THE PREFERRED EMBODIMENTS

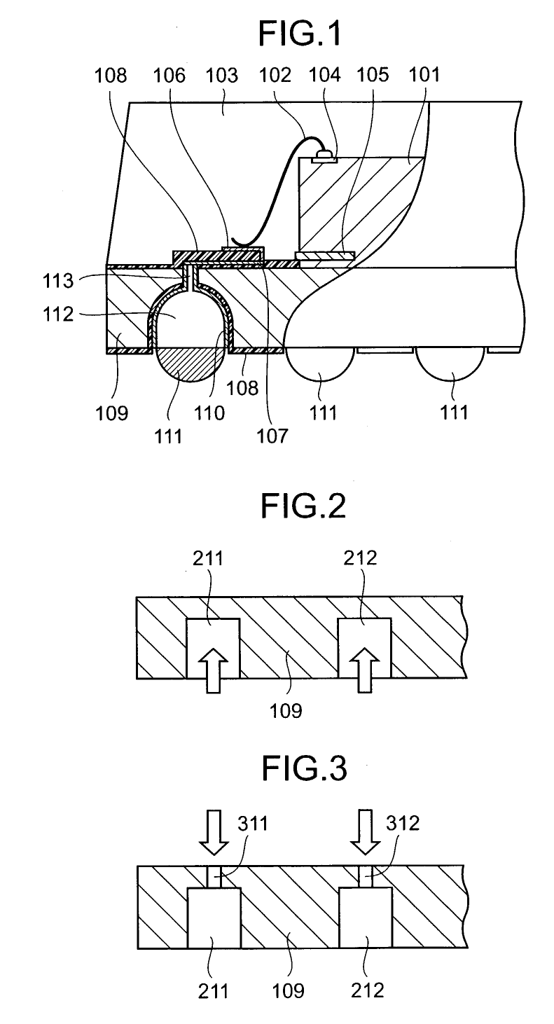

Referring to FIG. 1, a semiconductor device according to an embodiment of the present invention employs a metal substrate. That is, in a semiconductor device having large calorimetric power due to large current consumption thereof, a substrate 109 for mounting a semiconductor chip 101 such as IC or LSI, etc., on one surface thereof and solder balls 111 on the other surface thereof is formed of a metal material. Copper, titanium or iron, etc., may be used as the metal material to form the substrate 109.

A plurality of holes 112 for supporting the solder balls 111 are formed in the other surface of the metal substrate 109 on which the solder balls 111 are mounted by etching, drilling or laser machining of the substrate. In the one surface of the metal substrate 109, a corresponding number of holes 113 each having diameter smaller than that of the solder ball supporting hole 112 are formed in corresponding positions similarly. The solder ball supporting holes 112 and the smaller holes 113 are in communication with each other to form the corresponding number of through-holes.

Further, an insulating film 108 of silicon oxide, titanium oxide, aluminum nitride or resin is formed on a whole surface of the substrate including inner surfaces of the through-holes by vapor-deposition or adhesion, etc., and then a first wiring layer 107 of electrically conductive metal such as copper or aluminum is formed on the insulating film 108 on the one surface of the substrate 109.

By repeating similar operation, a wiring, which takes in the form of a lamination of wiring layers is obtained. Thereafter, the semiconductor chip 101 is bonded onto the metal substrate 109 by using an adhesive and bonding wires 102 are connected to bonding pads 104 of the semiconductor chip 101 by the wire-bonding process and the semiconductor chip 101 and the bonding wires are resin-sealed. Alternatively, the bonding wires may be connected to the pads by using bump contacts and resin sealing. An electrically conductive metal film is also vapor-deposited on the inner surface of each of the through-holes and the solder balls 111 are put in the respective solder ball supporting holes 112 and bonded into the solder ball supporting holes 112 by reflow to improve the heat radiation. Thus, the semiconductor device of the present invention can be fabricated with low cost.

Describing this in more detail with reference to FIG. 1, the solder ball supporting hole 112 formed in the other surface, that is, a lower surface, of the substrate 109 of copper 125 μm thick takes in the form of a hanging bell. Such solder ball supporting hole 112 has a diameter slightly small than a diameter of the solder ball, which is, for example, about 400 μm, and can be obtained by etching the metal substrate 109 to a depth of about 100 μm from the lower surface of the metal substrate 109.

Thereafter, the smaller holes 113 each having a diameter of about 30 μm are formed in the one surface, that is, an upper surface of the metal substrate 109 to a depth of about 25 μm by etching from the upper surface such that the smaller holes 113 communicate with the respective solder ball supporting holes 112. The insulating film 108 may be formed by oxidizing the whole surface of the metal substrate 109. Thereafter, the surface of the insulating film 108 on the upper surface of the substrate 109 is painted with resist liquid to form a resist film and the first wiring layer 107 is formed on the upper surface of the substrate 109 by exposing the resist film. In this case, an electrically conductive metal layer 110 of the same material as that of the wiring is formed on the inner surface of each solder ball supporting hole 112.

In this manner, the solder ball supporting hole 112 and the smaller hole 113 are connected each other to form the through-hole. Thereafter, a second wiring layer 106 and a necessary number of subsequent wiring layers are formed on the upper surface of the metal substrate 109, resulting in the required wiring. And then, the semiconductor chip 101 is mounted thereon and the electrodes of the semiconductor chip 101 are electrically connected to the wiring by the wire-bonding.

The upper surface of the substrate 109 including the semiconductor chip 101 and the wiring is sealed by resin 103 and then the solder balls 111 are mounted in the solder ball supporting holes 112.

FIG. 2 to FIG. 8 are cross sectional views of the semiconductor device shown in FIG. 1, illustrating a fabrication flow according to the present invention. As shown in FIG. 2, the lower surface of the substrate 109 is first painted with resist liquid to form the resist film. Predetermined portion of the resist film are exposed and solder ball supporting holes (211, 212) each having diameter slightly smaller than the diameter of the solder ball 111 are formed by etching the exposed portions of the metal substrate 109. For the substrate 109 having thickness of 125 μm, each of the solder ball supporting holes (211, 212) etched to a depth of about 100 μm becomes a hanging bell shape.

Thereafter, holes (311, 312) each having a diameter of about 30 μm are formed in the upper surface of the substrate similarly, as shown in FIG. 3.

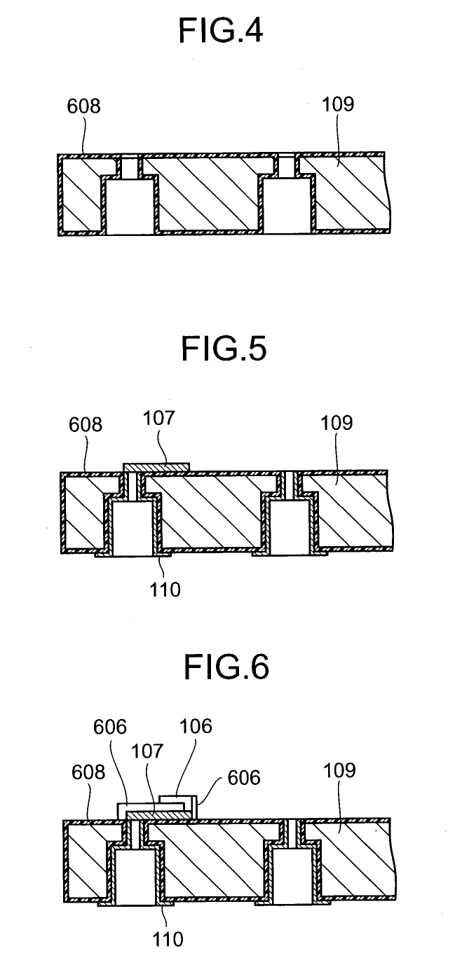

Thereafter, the whole surface of the substrate 109 is oxidized by oxidation agent to form a metal oxide insulating film 608 as shown in FIG. 4. And then, as shown in FIG. 5, the both surfaces of the substrate 109 are painted with resist liquid to form the resist film and predetermined portions thereof are exposed. And then, the resist film is removed and an electrically conductive metal is vapor-deposited on the predetermined portions of the upper surface of the substrate 109 to form the first wiring layer 107 and the conductive layer 110 on the inner surface of the hanging bell shaped holes. Thereafter, an insulating film 606 is formed on the upper surface of the substrate similarly, as shown in FIG. 6 and then the second wiring layer 106 is formed. The third and subsequent wiring layers are formed similarly.

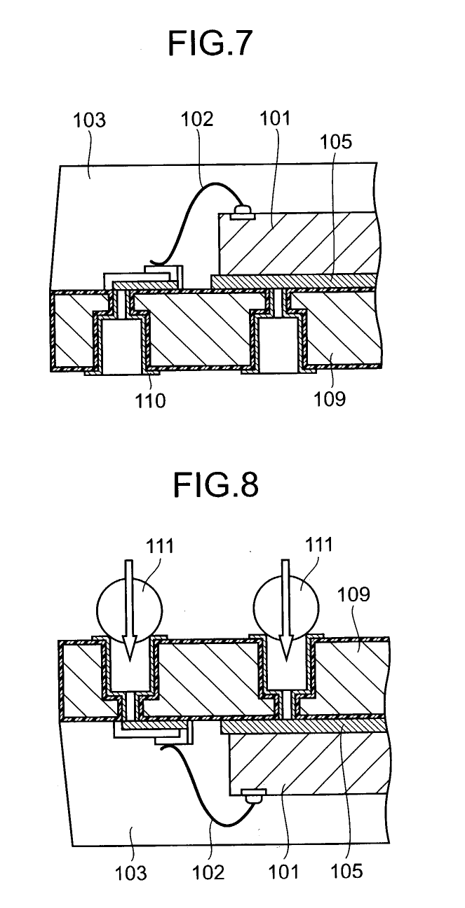

Thereafter, the semiconductor chip 101 is mounted on the upper surface of the substrate 109 by using adhesive 105 and the electrodes of the semiconductor chip 101 are wire-bonded to the second wiring 106 and then the substrate 109 mounting the semiconductor chip 101 is sealed by resin 103, as shown in FIG. 7. Thereafter, the resin sealed substrate 109 is turned up side down and the solder balls 111 are put on the solder ball supporting holes, as shown in FIG. 8. Thereafter, the solder balls 111 are flown into the solder ball supporting holes 112 by reflow, so that the conductive layer 110 is connected to the first wiring layer 107.

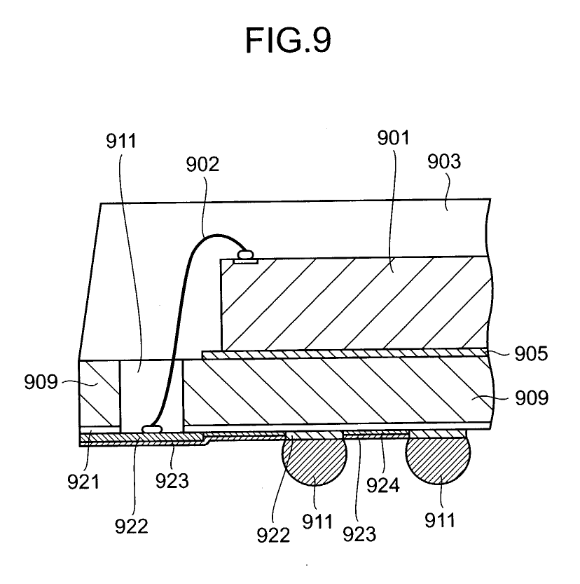

Next, a semiconductor device according to a second embodiment of the present invention will be described with reference to FIG. 9. In FIG. 9, a plurality of bonding holes 911 are formed in portions of a copper substrate 909 in which wire-bonding is to be performed, by etching, drilling or laser-machining, etc.

A copper foil 922 is adhered to a lower surface of the copper substrate 909 by using adhesive 905. A portion of the copper foil 922 exposed in the bonding holes 911, which becomes a bonding pad, has no adhesive. In order that bonding pads and regions on which solder balls are mounted are electrically connected each other, the copper foil 922 is patterned to form a wiring 924. Alternatively, the wiring 924 between the bonding pad and the regions on which the solder balls are to be mounted may be formed by vapor-deposition instead of the patterning of the copper foil.

A semiconductor chip 901 is mounted on the substrate 909, which is machined in this manner, by adhesive 905 and the wire-bonding is performed. The wire-bonding may be performed by bonding one end of the bonding wire 902 to the copper foil 922 and then the other end thereof to the bonding pad of the semiconductor chip 902 by mean of the so-called reverse bonding technique. With such scheme, it is possible to minimize the diameter of the bonding hole 911 formed in the substrate. Other portion of the substrate than portions in which the solder balls are to be mounted is covered by an insulating film 923 and then the solder balls 911 are mounted on the solder ball mounting regions.

As described hereinbefore, according to the semiconductor device of the present invention in which the semiconductor chip is directly mounted on the metal substrate formed of such as copper having high heat conductivity, the wiring is formed and then the solder balls are mounted thereon. Therefore, the heat spreader, which is indispensable conventionally, becomes unnecessary and, therefore, the mounting area can be reduced compared with the conventional semiconductor device.

What is claimed is:

1. A semiconductor device comprising:
a heat radiative substrate having one surface on which a semiconductor chip is mounted and a plurality of through-holes formed therein, said through-holes extending from said one surface to the other surface;
a plurality of solder balls electrically connected to a wiring provided on said substrate, said solder balls being arranged on said the other surface of said substrate;
bonding wires having one ends connected to bonding pads of said semiconductor chip and the other ends electrically connected to the plurality of said solder balls through said through-holes; and
resin for sealing said semiconductor chip and said bonding wires on said one surface of said substrate.

2. A semiconductor device as claimed in claim 1, wherein said substrate is formed of a metal material.

3. A semiconductor device as claimed in claim 2, wherein inner surfaces of said through-holes are covered by electrically conductive layer and said solder balls are supported by said through-holes.

4. A semiconductor device as claimed in claim 3, wherein a diameter of said through-hole in said one surface of said substrate is smaller than a diameter of said through-hole in said the other surface of said substrate, by which said solder ball is supported.

5. A semiconductor device as claimed in claim 2, further comprising an insulating film formed on a whole of said one surface of said substrate and a wiring formed by a lamination of a plurality of electrically conductive metal wiring layers formed on said insulating film.

6. A semiconductor device as claimed in claim 2, wherein said the other ends of said bonding wires pass through said through-holes and are electrically connected to said wiring provided on said the other surface of said substrate.

7. A semiconductor device as claimed in claim 2, wherein said metal material is selected from a group consisting of copper, titanium, aluminum and iron.

8. A semiconductor device as claimed in claim 5, wherein said insulating film is formed of a material selected from a group consisting of silicon oxide, titanium oxide, aluminum nitride and resin.
